(19) United States
(12) Patent Application Publication
(10) Pub. No.: US 2016/0155501 A1
(43) Pub. Date: Jun. 2, 2016

(54) METHOD OF PROGRAMMING A RESISTIVE RANDOM ACCESS MEMORY

(71) Applicants: COMMISSARIAT A L'ENERGIE ATOMIQUE ET AUX ENERGIES ALTERNATIVES, Paris (FR); UNIVERSITE JOSEPH FOURIER GRENOBLE, Grenoble Cedex 9 (FR)

(72) Inventors: Elisa VIANELLO, GRENOBLE (FR); Daniele GARBIN, COLLEGNO (IT)

(21) Appl. No.: 14/956,838

(22) Filed: Dec. 2, 2015

(30) Foreign Application Priority Data
Dec. 2, 2014 (FR) 1461761

(51) Int. Cl. G11C 13/00

(52) U.S. Cl. CPC G11C 13/0069; G11C 13/0097; G11C 2013/0078; G11C 2013/0083; G11C 2013/009

(57) ABSTRACT

A method of programming a resistive random access memory switching from an insulating state to a conducting state, the memory including first and second electrodes separated by an electrically insulating material, and switching for the first time from the insulating state to the conducting state by applying a threshold voltage between the electrodes, with a first limited current flowing in the memory after the switching, the first limited current being limited by a current limitation device, the method including applying a voltage between the electrodes for the switching of the resistive random access memory from a highly resistive conducting state to a low resistive conducting state, with a second limited current flowing in the resistive random access memory after the switching, the second limited current being limited by the current limitation device, the second limited current being chosen strictly less than the first limited current.

### CROSS-REFERENCE TO RELATED APPLICATIONS

This application claims priority to French Patent Application No. 1461761, filed Dec. 2, 2014, the entire content of which is incorporated herein by reference in its entirety

### FIELD

This invention relates to the field of non-volatile rewritable memories, and more specifically to that of resistive random access memories of the OxRRAM type and of the CBRAM type. A resistive random access memory comprises first and second electrodes separated by a layer of electrically insulating material, and switches from an insulating state to a conducting state by application of a threshold voltage VSET between the first and second electrodes.

### BACKGROUND

According to the target applications and performance, various types of memories are used.

As such, memories of the SRAM type, or static random access memories, offer ultra-fast write times, required for example during calculations by a micro-processor. The major disadvantage with these memories is that they are volatile and that the relatively large size of the memory point does not make it possible to obtain a large storage capacity in a reasonable volume.

Memories of the DRAM type, or dynamic random access memories, carrying out the storage of electric charges in capacities, offer a large storage capacity. These memories however have higher write times (a few tens of nanoseconds) than those of memories of the SRAM type and are also volatile, with the retention time of the information being about a few tens of milliseconds.

Inversely, for applications that require a storage of the information even when the voltage is cut off, solid-state memory devices are also known which retain the information in the absence of power: these devices are called non-volatile memories. As such, for many years, various technological solutions have been developed, and have led to the availability of non-volatile memories that can be written and erased electrically. The following for example can be mentioned:
EPROMs (“Erasable Programmable Read Only Memories”), of which the content can be written electrically, but which have to be subjected to UV radiation in order to erase the memorised information;
EEPROMs (“Electrically Erasable Programmable ROMs”), of which the content can be written and erased electrically, but which require, in order to create them, more substantial semiconductor surfaces than memories of the EPROM type, and which are therefore more expensive to produce.

As the two solutions mentioned hereinabove have limits in their application, manufacturers have begun searching for an ideal non-volatile memory, that would combine the following characteristics: electrical write and erasure, high density and low cost per bit, random access, short read and write times, good endurance, but also low power consumption and low supply voltage.

Non-volatile memories also exist, called Flash memories, which do not have the disadvantages of EPROM or EEPROM memories mentioned hereinabove. Indeed, a Flash memory is formed from a plurality of memory cells that can be programmed electrically individually, a large number of cells, called a block, sector or page, being able to be erased simultaneously and electrically. Flash memories combine both the advantage of EPROM memories in terms of integration intensity and the advantage of EEPROM memories in terms of electrical erasure.

In addition, the sustainability and the low power consumption of Flash memories make them interesting for many applications: digital cameras, cellular telephones, printers, personal assistants, portable computers, or portable audio playing and recording devices, USB keys, etc. In addition, Flash memories do not have mechanical elements, which provides them with rather substantial resistance to impacts. In the “all digital” era, these products have developed widely, allowing for an explosion in the Flash memory market.

Most off-the-shelf non-volatile Flash memories use the storage of charges as a principle for encoding information. In practice, a charge-trapping layer (generally polysilicon, or a dielectric such as SiN) is encapsulated between two dielectrics in a MOS transistor gate stack. The presence or the absence of a charge in this medium modifies the conduction of the MOS transistor and makes it possible to encode the state of the memory.

More recently, other types of non-volatile rewritable memories have appeared in order to reduce the voltages and programming time of Flash memories; in particular ferroelectric memories (FeRAM or “Ferroelectric RAM” memories) can be mentioned, based on polarisation switching, or magnetic memories (MRAM or “Magnetic RAM” memories) that use the direction of the remanent magnetic field in the active material. However, FeRAM and MRAM memories have difficulties that limit their downscaling.

In order to overcome these difficulties, variable resistance memories (called RRAM or “Resistive RAM” memories) are known; the latter are today the subject of great attention. Memories of the resistive type can have at least two “off” or “on” states corresponding to the switching from a resistive state (“HRS” state) to a less resistive state (“LRS” state)).

Variable resistance random access memories are today the subject of great attention, due in particular to their low power consumption and their high operating speed.

The binary data 0 or 1 is stored in a Metal/Insulation/Metal (MIM) structure that has two separate resistance states. FIG. 1 shows the structure of a memory cell RRAM 1 of the MIM type. This device 1 is formed by a stack comprising an active memorisation zone 2 arranged between a lower conducting electrode 3 and a higher conducting electrode 4.

As such, the memory cell of the resistive type can reversibly switch from a highly resistive state “HRS” (“High Resistance State”), also referred to as the “OFF” state, to a low resistive state “LRS” or “ON” state. It can therefore be used to store binary information.

The write mechanism is called SET in the framework of RRAMs and consists in switching from the HRS state to the LRS state. In order to erase the information, the active material is switched from the LRS state to the HRS state, with the erasure mechanism being called RESET. The LRS and HRS state are both conductors (with of course a better conduction of the LRS state in relation to the HRS state); but in the initial state, the active material of the active memorisation zone 2 is insulating (PRS state, “Pristine Resistance State”). A first electric stress therefore has to be applied on the blank memory cell in order to generate the LRS state for the first time. The associated process, called FORMING, consists in a breakdown that is partially reversible of the active material, i.e. after the switching from the insulating state PRS to the conducting state LRS, the resistance of the conducting state can be switched on the HRS state with a lower electric stress (RESET operation).

The phenomenon of the change in resistance is observed in different types of materials, which suggests mechanisms of different operations. Several types of resistive memories can as such be distinguished. The field of this invention relates more particularly to two categories of resistive memories:
memories comprising an active zone based on an active material with an oxide base (OxRRAM or “Oxide RRAM” memory) such as a binary oxide of a transition metal;
memories comprising an active zone based on an ionically conductive material (CBRAM or “Conductive Bridging RAM” memories) forming a solid electrolyte with an ionic conduction arranged between an electrode forming an inert cathode and an electrode comprising a portion of ionisable metal, i.e. a portion of metal that can easily form metal ions, and forming an anode.

The operation of CBRAM memories is based on the formation, within the solid electrolyte, of one or several metal filaments (also called “dendrites”) between its two electrodes when these electrodes are brought to suitable potentials. The formation of the filament makes it possible to obtain a given electrical conduction between the two electrodes. By modifying the potentials applied to the electrodes, it is possible to modify the distribution of the filament, and as such to modify the electrical conduction between the two electrodes. For example, by inverting the potential between the electrodes, it is possible to reduce the metal filament or cause it to disappear, in such a way as to suppress or substantially reduce the electrical conduction due to the presence of the filament. In the “HRS” state, the metal ions coming from the portion of ionisable metal of the soluble electrode are dispersed in the entire solid electrolyte. As such, no electrical contact is established between the cathode and the anode, i.e. between the upper electrode and the lower electrode. The solid electrolyte comprises an electrically insulating zone of great resistivity between the anode and the cathode. When a positive potential VSET is applied to the anode, an oxidizing-reducing reaction takes place at this electrode, creating mobile ions. The ions are then displaced in the electrolyte under the effect of the electric field applied to the electrodes. Arriving at the inert electrode (the cathode), the ions are reduced, driving the growth of a metal filament. The filament grows preferentially in the direction of the soluble electrode. The memory then switches to the “LRS” state when the filament allows for contact between the electrodes, rendering the stack conductive. This phase constitutes the “SET” of the memory.

To switch to the “HRS” state (“RESET” phase of the memory), a negative VRESET voltage is applied on the anode, driving the dissolution of the conductive filament.

As this entails OxRRAM memories, as with the CBRAM memories, the filament model benefits from a large consensus. It therefore also reposes on the formation and the rupture of one or several conduction paths (conductive filaments) on the oxide matrix, connecting the two electrodes. The formation and the rupture of the conductive filaments are attributed to the presence of lacks in oxygen.

It is important to note that, in the case of OxRRAMs such as in the case of CBRAMs, the SET operation makes it possible to switch the memory cell from a highly resistive state HRS to a low resistance state LRS. As mentioned hereinabove, the SET is carried out by applying a sufficient VSET voltage to the terminals of the memory element. The transition between the high and low resistance state (close to an oxide breakdown in the case of an OxRRAM memory) is very fast and results in an abrupt increase in the current when the voltage VSET is reached. This abrupt increase in the current is not self-limited. If nothing is done to control this increase the current will increase until very high values able to result in a very substantial increase in the temperature and a destruction of the memory device. It is therefore necessary to limit the increase in the current to a certain value in order to obtain a low resistance state while still maintaining an intact memory device. This limited current ICSET is called indifferently current limitation or balancing power (“compliance”).

The current limitation required during the write operation can be carried out by different device such as a resistor or a transistor in series with the memory: the adding of a resistor or of a transistor in series makes it possible to limit the current flowing in the memory point and series resistor/transistor set. The advantage of using a transistor in relation to a series resistor is to be able to control the level of the limitation using the gate voltage. The higher the gate voltage is, the higher the current saturation will be. The transistor as such acts as a device configured to adjust the current limitation in the memory element.

A path for development relates to the endurance of OxRRAM and CBRAM memories, i.e. the number of write/erasure cycles, in other words the number of “SET”/“RESET” cycles of a memory element that can be successfully carried out. Good endurance, i.e. a large number of cycles, is a property that is desired for a memory as this makes it possible to modify many times the information which is stored in the memory. Chen et al., in their article “Balancing SET/RESET Pulse for>10¹⁰ Endurance in HfO₂ 1T1R Bipolar RRAM” (IEEE Transactions On Electron Devices, pp. 3243-3249, Vol. 59, No. 12, December 2012) study the impact of the “SET” and “RESET” conditions on the endurance of an OxRRAM memory. Two different mechanisms for endurance rupture are as such revealed:
a first endurance rupture mechanism is linked to programming conditions that are too low, i.e. to a limited current ICSET during the “SET” operations and to programming voltages that are too low: in this first case, the memory cell is blocked in a state of high resistance HRS, typically close to the PRS state;
a second endurance rupture mechanism is linked to programming conditions that are too high, i.e. to a limited current ICSET during “SET” operations and to programming voltages that are too high: in this second case, the memory cell is blocked in a low resistance state LRS.

The article recommends searching for balanced “SET” conditions, and in particular a suitable limited current ICSET, in order to improve the endurance of a memory cell.

Another path for development relates to the decrease in the energy required in order to carry out the “SET” and “RESET” operations in order to reduce the power consumption of the memory. The power required for the “SET” and “RESET” operations of a memory element is in particular determined by the programming conditions in ICSET current and in VRESET voltage. It is in particular sought to use a limited current ICSET during the “SET” operations that is as low as possible, in order to contribute in reducing the power consumption of the memory element, while still having the best endurance possible, i.e. typically an endurance greater than 10⁶ cycles.

### SUMMARY

An aspect of the invention provides a solution to the problems mentioned hereinabove, by proposing a method of programming a resistive random access memory that makes it possible to minimise the power consumption of the resistive random access memory while still having a great endurance, typically greater than 10⁶ cycles, for the resistive random access memory. In other words, an aspect of the invention provides a solution to the problem of the reduction in the endurance of a resistive random access memory during the use of low programming conditions, which it is sought to not increase in order to no increase the power consumption of the resistive random access memory.

An aspect of the invention as such relates to a method of programming a resistive random access memory switching from an insulating state to a conducting state, the memory comprising a first electrode and a second electrode separated by a layer of electrically insulating material, and switching for the first time from the insulating state to the conducting state by application of a threshold voltage VFORMING between the first and second electrodes, with a first limited current ICFORMING flowing in the memory after the switching from the insulating state to the conducting state, with the first limited current ICFORMING being limited by a current limitation device, with the method of programming comprising a step referred to as the “SET step” during which a voltage VSET is applied between the first and second electrodes for the switching of the resistive random access memory from a highly resistive conducting state to a low resistive conducting state, with a second limited current ICSET flowing in the resistive random access memory after the switching from the highly resistive conducting state to the low resistive conducting state, with the second limited current ICSET being limited by the device for current limitation, the second limited current ICSET being chosen strictly less than the first limited current ICFORMING.

Thanks to an embodiment of the invention, during the programming of a resistive random access memory a second limited current ICSET strictly less than the first limited current ICFORMING is beneficially used in order to improve the endurance of the resistive random access memory while still minimising its power consumption. The applicant has indeed surprisingly observed that the use of a second limited current ICSET strictly less than the first limited current ICFORMING makes it possible to improve the endurance of the resistive random access memory while still minimising its power consumption.

An explication of this behaviour could be that a first conductive filament is formed between the first and second electrodes of the resistive random access memory during a step of FORMING, and that the characteristics of this first conductive filament depend on the first limited current ICFORMING. The first conductive filament is then partially suppressed during a RESET step; a portion of the first conductive filament subsists at the end of the RESET step. During the SET step, it is estimated that a second conductive filament is formed between the first electrode and the residual portion of the first conductive filament. The characteristics of the second conductive filament depend on the second limited current ICSET. As such, the second limited current ICSET being strictly less than the first limited current ICFORMING, the first and second conductive filaments do not have the same characteristics. The low resistive conducting state after the step of FORMING is less resistive than the low resistive conducting state after the SET step, with ICFORMING>ICSET. It is estimated that the residual portion of the first conductive filament behaves like a reservoir during the formation of the second conductive filament during each SET step, which makes it possible to increase the number of SET/RESET cycles that it is possible to carry out with the resistive random access memory.

In addition to the characteristics that have just been mentioned in the preceding paragraph, the method of programming a resistive random access memory according to an aspect of the invention can have one or more additional characteristics among the following, considered individually or according to all of the technically permissible combinations:
The method of programming according to an aspect of the invention comprises, prior to the SET step, the following steps:
   a step referred to as the “FORMING step” during which the threshold voltage VFORMING is applied between the first and second electrodes for switching the resistive random access memory from the initial insulating state to the low resistive conducting state, with the first limited current ICFORMING flowing in the resistive random access memory after the switching from the initial insulating state to the low resistive conducting state;
   a step referred to as the “RESET step” during which a voltage VRESET is applied between the first and second electrodes for the switching of the resistive random access memory from the low resistive conducting state to the highly resistive conducting state.
The first limited current ICFORMING and the second limited current ICSET are such that:

$$1.5 \leq \frac{ICFORMING}{ICSET}$$

The first limited current ICFORMING and the second limited current ICSET are such that:

$$\frac{ICFORMING}{ICSET} \leq 5$$

According to an embodiment, the resistive random access memory to be programmed by the method of programming according to an aspect of the invention is a memory of the OxRRAM type.
According to another embodiment, the resistive random access memory to be programmed by the method of programming according to an aspect of the invention is a memory of the CBRAM type.

The invention and its various applications shall be better understood when reading the following description and in examining the figures that accompany it.

### BRIEF DESCRIPTION OF THE FIGURES

The figures are presented for the purposes of information and do not limit the invention in any way.

FIG. 1 diagrammatically shows a memory device of the OxRRAM or CBRAM type.

FIG. 2 diagrammatically shows the change in the switching power of a memory device according to the limited current ICSET flowing in the memory device during each “SET” operation, and for various given values of voltage VRESET applied to the memory device during each “RESET” operation.

FIGS. 3a, 3b, 3c and 3d diagrammatically show the steps of a method of programming a resistive random access memory according to a first embodiment of the invention.

FIG. 4 is a diagram of the steps of the method of programming a resistive random access memory according to the first embodiment of the invention.

FIGS. 5a, 5b and 5c diagrammatically show the change in endurance of a memory device according to the ratio between a first limited current ICFORMING flowing in the memory device during a step referred to as the “FORMING step” of the method of programming according to the invention and a second limited current ICSET flowing in the memory device during a step referred to as the “SET step” of the method of programming according to an embodiment of the invention.

FIG. 6 diagrammatically shows the change of the ratio between the first limited current ICFORMING and the second limited current ICSET according to the voltage VRESET applied to the memory device during each “RESET” operation, for a given endurance value.

### DETAILED DESCRIPTION

Unless mentioned otherwise, the same element appearing in different figures has a unique reference.

In this description, the terms “limited current”, “current limitation” or “balancing current” (“compliance”) are used indifferently. The terms “initial state PRS”, “insulating state PRS”, “initial insulating state PRS” or “PRS state” (“Pristine Resistance State”) are used indifferently. The terms “low resistive conducting state”, “low resistive state LRS” and “LRS state” (“Low Resistive State”) are used indifferently. The terms “high resistance conducting state HRS”, “high resistance state HRS” and “HRS state” (“High Resistive State”) are used indifferently.

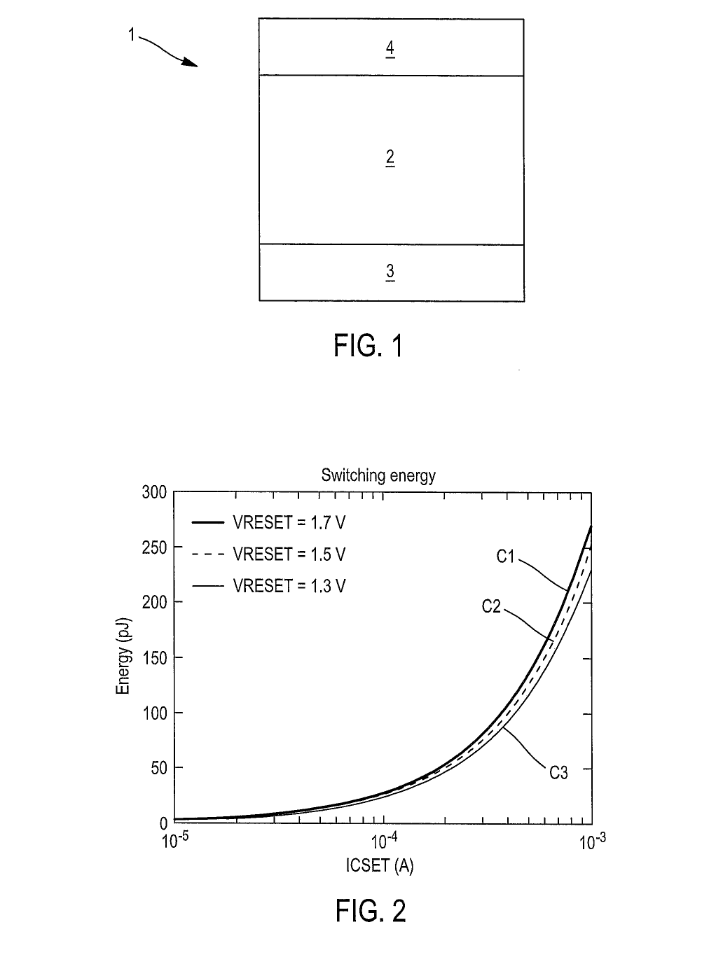

FIG. 1 was described hereinabove.

FIG. 2 diagrammatically shows the change in the switching power of a resistive random access memory according to the limited current ICSET flowing in the resistive random access memory during each “SET” operation, and for various different given values of voltage VRESET applied to the resistive random access memory during each “RESET” operation.

FIG. 2 shows as such:
a first curve C1 of the switching energy of the resistive random access memory according to the limited current ICSET flowing in the resistive random access memory during each “SET” operation, for a voltage value VRESET applied to the resistive random access memory during each “RESET” operation of 1.7 V;
a second curve C2 of the switching energy of the resistive random access memory according to the limited current ICSET flowing in the resistive random access memory during each “SET” operation, for a voltage value VRESET applied to the resistive random access memory during each “RESET” operation of 1.5 V;
a third curve C3 of the switching energy of the resistive random access memory according to the limited current ICSET flowing in the resistive random access memory during each “SET” operation, for a voltage value VRESET applied to the resistive random access memory during each “RESET” operation of 1.3 V.

The first, second and third curves C1, C2 and C3 show that the higher the voltage VRESET of each “RESET” operation is, the higher the switching power of the resistive random access memory, for a given value of limited current ICSET of each “SET” operation, is.

The first, second and third curves C1, C2 and C3 show also that the higher the current ICSET of each “SET” operation is, the higher the switching power of the resistive random access memory, for a given value of tension VRESET of each “RESET” operation, is.

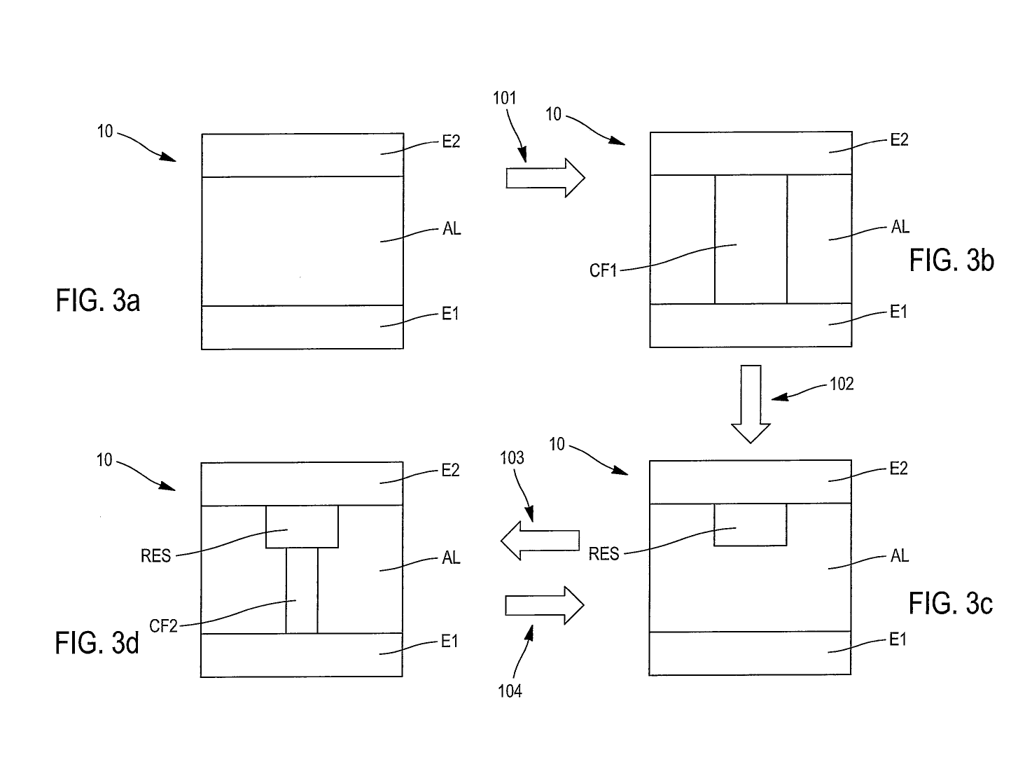

FIGS. 3a, 3b, 3c and 3d diagrammatically show the steps of the method 100 of programming a resistive random access memory 10 according to a first embodiment of the invention. FIGS. 3a, 3b, 3c and 3d are described jointly.

FIG. 3a shows a resistive random access memory 10 comprising an active memorisation zone AL arranged between a first conducting electrode E1, or lower electrode, and a second conducting electrode E2, or upper electrode. The resistive random access memory 10 of FIG. 3a is in an initial insulating state PRS.

The method 100 of programming according to an aspect of the invention is described in more detail in what follows in the case of a resistive random access memory 10 of the OxRRAM, or “Oxide RRAM”, type, comprising an active memorisation zone AL based on an active material with an oxide base, such as a binary oxide of a transition metal, surrounded by two metal electrodes. This is therefore a Metal-Oxide-Metal structure based on the change in resistance of the oxide layer which switches from a highly resistive state HRS to a low resistive state LRS when a sufficient write voltage VSET is applied at the terminals of the electrodes, and which switches from a low resistive state LRS to a highly resistive state HRS when a sufficient erasure voltage VRESET is applied at the terminals of the electrodes. There is a large number of binary oxides that have the capacity to change resistance reversibly. These memories can be bipolar, i.e. with SET and RESET voltages of opposite signs, or unipolar, i.e. with SET and RESET voltages of the same sign. They can also operate in certain cases in both modes, bipolar and unipolar. The resistive random access memory 10 is for example an OxRRAM memory of the TiN/Ti/HfO₂/TiN type, therefore having a first lower electrode E1 made of TiN, an active zone AL made of HfO₂ and an upper second electrode E2 formed from a TiN/Ti bilayer. Alternatively, the resistive random access memory 10 can be an OxRRAM memory of the TiN/Hf/HfO₂/TiN type, or an OxRRAM memory of the Ti/HfO₂/TiN type, or an OxRRAM memory of the Pt/TiO₂/Pt type, or an OxRRAM memory of the Ta/TaOₓ/TiN type. The examples of OxRRAM memory hereinabove are provided for the purposes of information and are not restrictive.

The method 100 of programming according to an aspect of the invention also applies to resistive random access memories of the CBRAM type, that have a solid electrolyte arranged between an electrode forming an inert cathode and an electrode comprising a portion of ionisable metal—contrary to resistive random access memories of the OxRRAM type, of which the metal electrodes are chosen to be less easily ionisable. An example of CBRAM memory is for example formed by a stack comprising a solid electrolyte, for example with a doped chalcogenide (ex. GeS) or oxide (ex. Al₂O₃) base, arranged between a lower electrode, for example of Pt, forming an inert cathode, and an upper electrode comprising a portion of ionisable metal, for example copper, forming an anode.

FIG. 3b shows the resistive random access memory 10 after a first step 101, referred to as “FORMING”. During the step 101 of FORMING, a threshold voltage VFORMING is applied between the first electrode E1 and the second electrode E2 for the switching of the resistive random access memory 10 from the initial insulating state PRS to a low resistive conducting state LRS. Under the effect of the threshold voltage VFORMING, a first conductive filament CF1 is formed in the active memorisation zone AL, between the first electrode E1 and the second electrode E2. During the step 101 of FORMING and after the switching of the resistive memory 10 from the initial insulating state PRS to the low resistive conducting state LRS, a first limited current ICFORMING flows in the resistive random access memory 10. The first limited current ICFORMING is typically limited by a limitation device, such as a transistor in series with the resistive random access memory 10.

FIG. 3c shows the resistive random access memory 10 after a second step 102, referred to as “first RESET”. During the step 102 of first RESET, a voltage VRESET is applied between the first electrode E1 and the second electrode E2 of the resistive random access memory 10, for the switching of the resistive random access memory 10 from the low resistive conducting state LRS to a highly resistive conducting state HRS. Under the effect of the application of the voltage VRESET, the first conductive filament CF1 is partially suppressed. At the end of the step 102 of first RESET, there subsists a residual portion RES of the first conductive filament CF1 in the active memorisation zone AL. The residual portion RES is typically in contact with the second electrode E2.

FIG. 3d shows the resistive random access memory 10 at the end of a third step 103, referred to as “SET”. During the step 103 of SET, a voltage VSET is applied between the first electrode E1 and the second electrode E2 of the resistive random access memory 10, for the switching of the resistive random access memory 10 from the highly resistive conducting state HRS to the low resistive conducting state LRS. Under the effect of the voltage VSET, a second conductive filament CF2 is formed in the active memorisation zone AL, between the first electrode E1 and the residual portion RES of the first conductive filament CF1. During the step 103 of SET and after the switching from the highly resistive conducting state HRS to the low resistive conducting state LRS, a second limited current ICSET flows in the resistive random access memory 10.

The second limited current ICSET is typically limited by a limitation device, such as a transistor in series with the resistive random access memory 10. In an embodiment, the same limitation device is used to limit the first limited current ICFORMING and to limit the second limited current ICSET, such as a transistor of which the level of limitation is varied using the gate voltage.

According to the method 100 of programming according to the first embodiment of the invention, the first limited current ICFORMING and the second limited current ICSET are chosen such that:

ICFORMING>ICSET

In an embodiment, the first limited current ICFORMING and the second limited current ICSET are also chosen such that:

$$1.5 \leq \frac{ICFORMING}{ICSET}$$

Finally, in an embodiment, the first limited current ICFORMING and the second limited current ICSET are also chosen such that:

$$\frac{ICFORMING}{ICSET} \leq 5$$

As such, in an embodiment, the first limited current ICFORMING and the second limited current ICSET are chosen such that:

$$1.5 \leq \frac{ICFORMING}{ICSET} \leq 5$$

The second limited current ICSET contributes in determining the value of the resistance of the resistive random access memory in its LRS state, as well as the programming power consumption. The value of the second limited current ICSET is therefore chosen first according to the value desired for the resistance of the resistive random access memory in its LRS state, and targeted performance in terms of programming power consumption. Then the value of the first limited current ICFORMING is chosen according to the value of the second limited current ICSET determined previously. The second limited current ICSET is typically between 10 μA and 1 mA. The first limited current ICFORMING is typically between 15 μA and 1.5 mA.

FIG. 3c, described hereinabove, also shows the resistive random access memory 10 at the end of a fourth step 104, referred to as “RESET”. During the step 104 of RESET, similarly to the step 102 of first RESET described hereinabove, the voltage VRESET is applied between the first electrode E1 and the second electrode E2 of the resistive random access memory 10, for the switching of the resistive random access memory 10 from the low resistive conducting state LRS to a highly resistive conducting state HRS. The voltage VRESET applied during the step 104 of RESET is, in an embodiment, identical to the voltage VRESET applied during the step 102 of first RESET. Under the effect of the application of the voltage VRESET, the second conductive filament CF2 is at least partially suppressed. At the end of the step 104 of RESET, the residual portion RES of the first conductive filament CF1 subsists in the active memorisation zone AL.

The third step of SET and the fourth step of RESET can then be repeated as many times as desired, within the limit of the endurance of the resistive random access memory 10. The endurance of the resistive random access memory 10 corresponds indeed to the number of SET/RESET cycles that it is possible to carry out before the resistive random access memory becomes blocked in one or the other state.

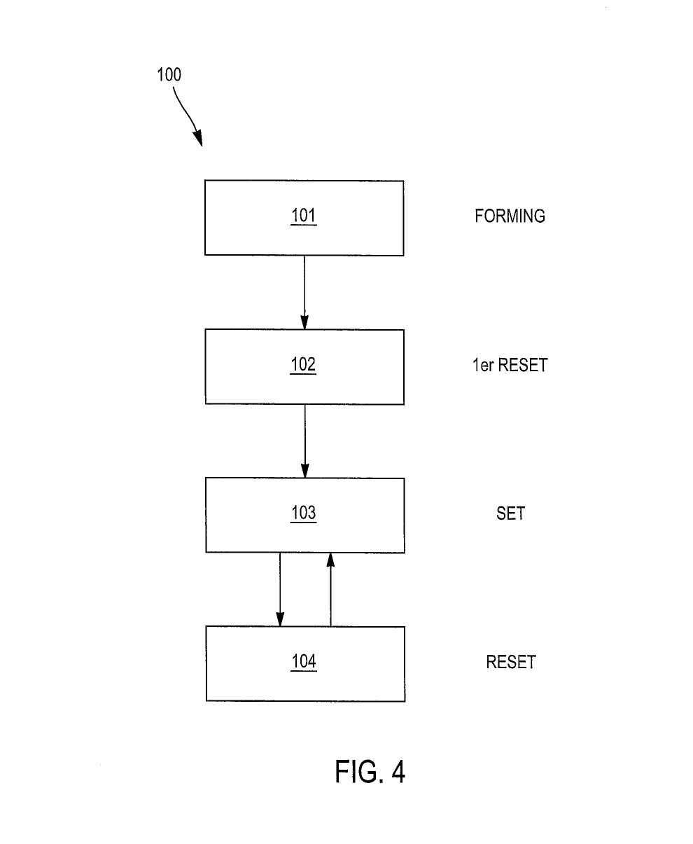

FIG. 4 is a diagram of the steps of the method 100 of programming the resistive random access memory 10 described hereinabove, according to the first embodiment of the invention. The method 100 as such successively comprises:
the first step 101 of FORMING;
the second step 102 of first RESET;
the third step 103 of SET;
the fourth step 104 of RESET.

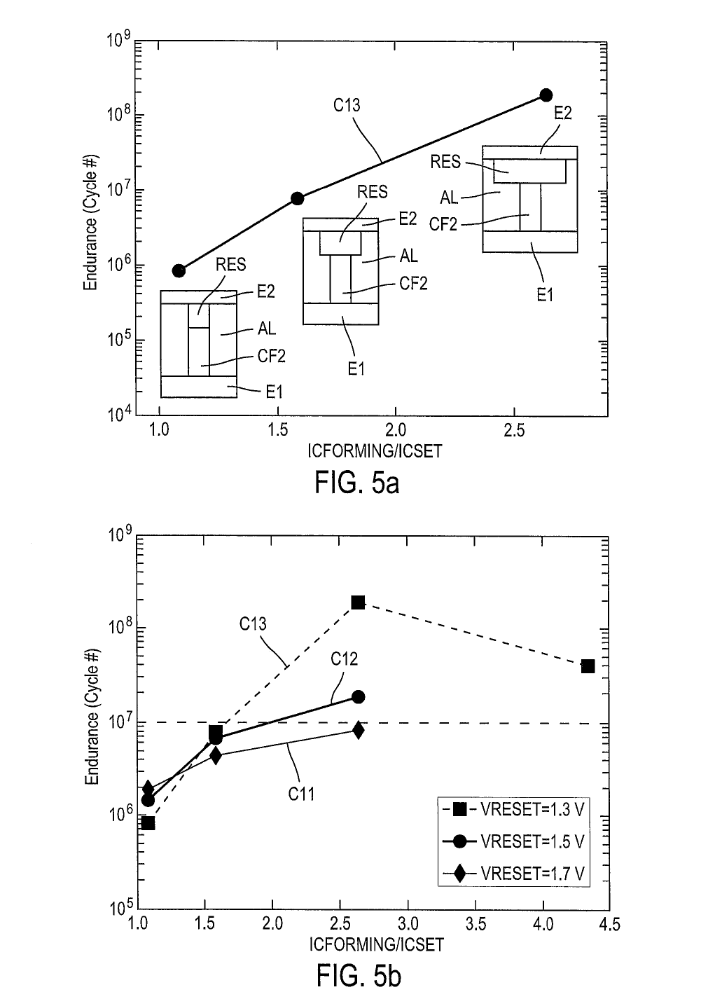

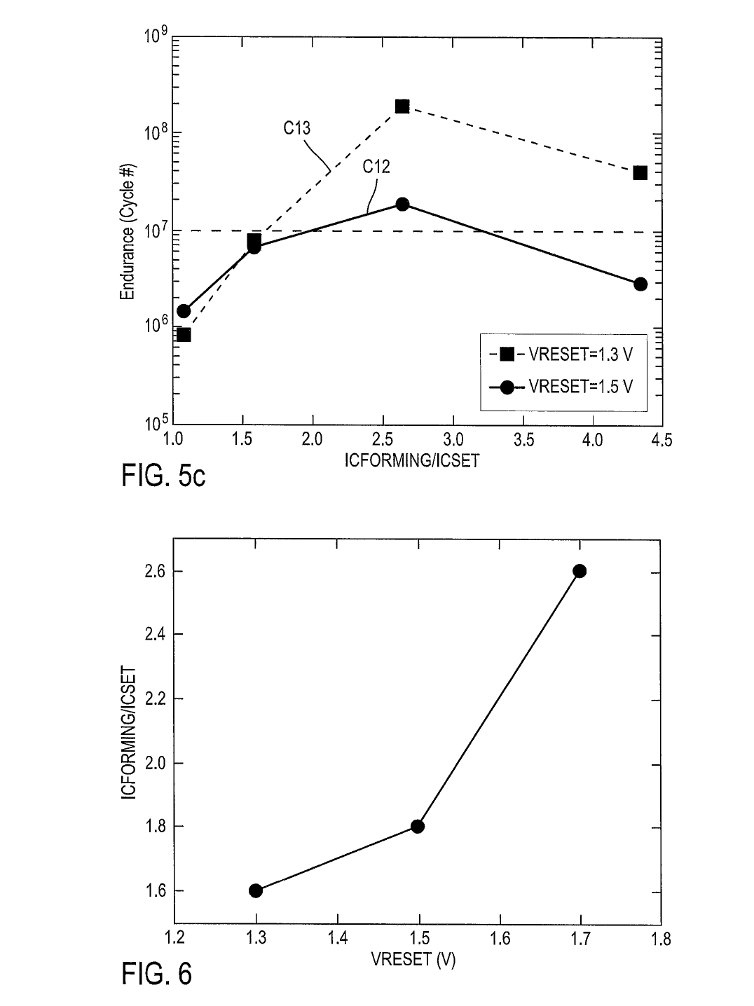

FIG. 5a shows an experimental curve C13 of the change in the endurance of the resistive random access memory 10 according to the ICFORMING/ICSET ratio between the first limited current ICFORMING and the second limited current ICSET, for a voltage VRESET of 1.3 V and for a second limited current ICSET of 230 μA. FIG. 5a shows that the performance in endurance of the resistive memory cell 10 increases when the first limited current ICFORMING is strictly greater than the second limited current ICSET. An explanation for this behaviour could be that the more the ICFORMING/ICSET ratio increases, the larger the reservoir formed by the residual portion RES of the first conductive filament CF1 is, as well as shown diagrammatically in FIG. 5a.

In addition to FIG. 5a, FIG. 5b diagrammatically shows the change in endurance of the resistive random access memory 10 described hereinabove, according to the ICFORMING/ICSET ratio between the first limited current ICFORMING and the second limited current ICSET, for different voltage values VRESET and for a second limited current ICSET of 230 μA.

FIG. 5b as such shows:
an experimental curve C11 of the change in endurance of the resistive random access memory 10 according to the ICFORMING/ICSET ratio between the first limited current ICFORMING and the second limited current ICSET, for a voltage VRESET of 1.7 V;
an experimental curve C12 of the change in endurance of the resistive random access memory 10 according to the ICFORMING/ICSET ratio between the first limited current ICFORMING and the second limited current ICSET, for a voltage VRESET of 1.5 V;
the experimental curve C13 of the change in endurance of the resistive random access memory 10 according to the ICFORMING/ICSET ratio between the first limited current ICFORMING and the second limited current ICSET, for a voltage VRESET of 1.3 V.

FIG. 5b shows that the performance in endurance of the resistive memory cell 10 increases when the first limited current ICFORMING is strictly greater than the second limited current ICSET. FIG. 5 also shows that the ICFORMING/ICSET ratio between the first limited current ICFORMING and the second limited current ICSET is desirably less than or equal to five. Indeed, a ICFORMING/ICSET ratio greater than five implies a high value for the first limited current ICFORMING, able to degrade the properties of the resistive random access memory 10.

In addition to FIG. 5b, FIG. 5c diagrammatically shows the change in endurance of the resistive random access memory 10 described hereinabove, according to the ICFORMING/ICSET ratio between the first limited current ICFORMING and the second limited current ICSET, for different voltage values VRESET and for a second limited current ICSET of 230 μA. FIG. 5c as such shows:
the experimental curve C12 of the change in endurance of the resistive random access memory 10 according to the ICFORMING/ICSET ratio between the first limited current ICFORMING and the second limited current ICSET, for a voltage VRESET of 1.5 V;
the experimental curve C13 of the change in endurance of the resistive random access memory 10 according to the ICFORMING/ICSET ratio between the first limited current ICFORMING and the second limited current ICSET, for a voltage VRESET of 1.3 V.

FIG. 6 is an experimental curve of the change in the ratio between the first limited current ICFORMING and the second limited current ICSET according to the voltage VRESET applied to the memory device during each “RESET” operation, for an endurance value of the resistive random access memory 10 of 10⁷ cycles.

Increasing the voltage value VRESET makes it possible to increase the memory window of the resistive random access memory 10, i.e. the HRS/LRS ratio between the resistance of the resistive random access memory 10 in its highly resistive state HRS and the resistance of the resistive random access memory 10 in its low resistive state LRS.

On the contrary, reducing the voltage value VRESET makes it possible to reduce the power consumption of the resistive random access memory 10. Indeed, for a given target endurance, for example of 10⁷ cycles in the particular example of FIG. 6, when the voltage value VRESET increases, the ICFORMING/ICSET ratio required to reach the target endurance increases. Therefore, when the voltage value VRESET increases, the power consumption of the resistive random access memory 10 increases, at a constant endurance.

FIG. 6 also shows that, for voltage values VRESET less than or equal to 1.7 V, the ICFORMING/ICSET ratio remains less than or equal to 2.6. FIG. 6 therefore shows that the method 100 of programming the resistive random access memory 10 according to the first embodiment of the invention remains functional when the value of the voltage VRESET increases.

1. A method of programming a resistive random access memory switching from an insulating state to a conducting state, said memory including a first electrode and a second electrode separated by a layer made of electrically insulating material, and switching for the first time from the insulating state to the conducting state by application of a threshold voltage VFORMING between the first and second electrodes, with a first limited current ICFORMING flowing in said resistive random access memory after the switching from the insulating state to the conducting state, with the first limited current ICFORMING being limited by a current limitation device, the method of programming comprising applying a voltage VSET between the first and second electrodes for switching the resistive random access memory from a highly resistive conducting state to a low resistive conducting state, with a second limited current ICSET flowing in the resistive random access memory after the switching from the highly resistive conducting state to the low resistive conducting state, the second limited current ICSET being limited by said current limitation device, the second limited current ICSET being chosen strictly less than the first limited current ICFORMING.

2. The method of programming as claimed in claim 1, further comprising, prior to the applying:
applying a voltage VRESET between the first and second electrodes for the switching of the resistive random access memory from the low resistive conducting state to the highly resistive conducting state.

3. The method of programming as claimed in claim 2, further comprising, prior to applying the voltage VRESET:
applying the threshold voltage VFORMING between the first and second electrodes for the switching of the resistive random access memory from the initial insulating state to the low resistive conducting state, with the first limited current ICFORMING flowing in the resistive random access memory after the switching from the initial insulating state to the low resistive conducting state.

4. The method of programming as claimed in claim 1, wherein the first limited current ICFORMING and the second limited current ICSET are such that:
$$1.5 \leq \frac{ICFORMING}{ICSET}$$

5. The method of programming as claimed in claim 1, wherein the first limited current ICFORMING and the second limited current ICSET are such that:
$$\frac{ICFORMING}{ICSET} \leq 5$$

6. A method comprising programming a memory of the OxRRAM type with the method as claimed in claim 1.

7. A method comprising programming a memory of the CBRAM type with a method as claimed in claim 1.
